(19) United States
(12) Patent Application Publication
(10) Pub. No.: US 2009/0026599 A1
(43) Pub. Date: Jan. 29, 2009

(54) Memory module capable of lessening shock stress

(75) Inventor: Wen-Jeng Fan, Hsinchu (TW)

Correspondence Address: Joe McKinney Muncy, PO Box 1364, Fairfax, VA, 22038-1364, US

(73) Assignee: POWERTECH TECHNOLOGY INC.

(21) Appl. No.: 11/878,891

(22) Filed: Jul. 27, 2007

(51) Int. Cl. H01L 23/02

(52) U.S. Cl. 257/685; 257/E23.18

(57) ABSTRACT

A memory module capable of lessening shock stresses, primarily comprises a multi-layer printed circuit board (PCB), a plurality of memory packages, and a stress-buffering layer. The memory packages are disposed at least on one of the rectangular surfaces of the PCB. The stress-buffering layer is disposed at least on both short sides of the PCB and extended to the two rectangular surfaces to reduce the impact stresses. Preferably, the stress-buffering layer is further disposed on the other long side of the PCB opposite to the one with disposed gold fingers.

### FIELD OF THE INVENTION

The present invention relates to a memory module for computer systems, especially, to a memory module capable of lessening shock stresses.

### BACKGROUND OF THE INVENTION

Memory modules are key components in desktop computers or notebook computers where memory modules can repeatedly plug into the sockets on a mother board for operations and calculations of the computer systems. The existing memory modules include SIMM (Single In-Line Memory Module), DIMM (Dual In-Line Memory Module), and SO-DIMM (Small Outline Dual In-Line Memory Module). During shipping, handling, and replacement, sometimes memory modules will accidentally drop to the ground. The existing memory modules can not stand the impact stresses and suffer damaged leading to electrical open.

As shown in FIG. 1, a conventional memory module 100 includes a multi-layer printed circuit board 110 and a plurality of memory packages 120 where the multi-layer printed circuit board 110 has two long sides 111 and two short sides 112. The memory packages 120 are disposed on the multi-layer printed circuit board 110. A plurality of gold fingers 113 are disposed on both surfaces of one of the long sides 111 of the multi-layer printed circuit board 110. A locking slot 114 is disposed on each short side 112 so as to mechanically fix in the socket when the memory module 100 is electrically connected. A drop test, or so-called impact test, is implemented to confirm the anti-dropping capability of the memory module 100. As shown in FIG. 2, the conventional memory module 100 is placed at a certain height H such as 50 cm or 100 cm and is released as a free fall and hit the concrete ground 10 with different impact angles. After the drop test, the memory module 100 will be tested to see if all the functions are normal. However, the existing memory module 100 can not stand the impact stresses leading to electrical open and fail the drop test. After failure analysis (FA), the major failure mode is the broken interfaces between the multi-layer printed circuit board 110 and the memory packages 120 caused by the impact stresses and leading to electrical open.

As shown in FIG. 3, the memory packages 120 can be Ball Grid Array (BGA) packages which include a plurality of solder balls 121 electrically connected to the ball pads 122 of the substrate without covering by the solder mask 123. Furthermore, a plurality of ball pads 115 are disposed on the multi-layer printed circuit board 110 without covering by the solder mask 116 for electrical connections to the solder balls 121. At the drop test, the memory module 100 will drop as a free fall and will eventually hit the ground where the impact stresses endure by the multi-layer printed circuit board 110 will transfer to the memory packages 120 leading to breakages 124 at the interfaces between the solder balls 121 and the ball pads 122. The memory module 100 is damaged and failed.

### SUMMARY OF THE INVENTION

The main purpose of the present invention is to provide a memory module capable of lessening shock stresses by using stress-buffering layers disposed on the edges of the multi-layer printed circuit board to reduce the impact stresses exerted on the memory module to prevent electrical open caused by dropping.

The second purpose of the present invention is to provide a memory module capable of lessening shock stresses by using stress-buffering layers to prevent moisture diffusion from the sidewalls of the multi-layer printed circuit board to enhance anti-humidity and product reliability.

According to the present invention, a memory module primarily comprises a multi-layer printed circuit board (PCB), a plurality of memory packages, and a stress-buffering layer. The PCB has a rectangular first surface, a rectangular second surface, a first long side, a second long side, and two short sides where a plurality of gold fingers are disposed on both surfaces of the first long side and at least a locking slot disposed on each short side. The memory packages are at least disposed on the first surface of the PCB and the stress-buffering layers are formed on two short sides and extended to the first surface and the second surface. A plurality of ball pads are disposed on the first surface of the PCB for joining the solder balls where the ball pads are Non-Solder Mask Defined Pad (NSMD) in one embodiment. The stress-buffering layer can prevent moisture diffusing into the PCB. Moreover, the stress-buffering can further be installed at the second long side. Parts of the memory packages may be also disposed on the second surface of the PCB.

### DESCRIPTION OF THE DRAWINGS

FIG. 1 shows a top view of a conventional memory module.

FIG. 2 shows the memory modules falling from a designated height and hitting the ground at different angles during drop tests.

FIG. 3 shows a partially cross-sectional view of the memory module to illustrate a broken solder ball after a drop test.

FIG. 4 shows a top view of a memory module according to the first embodiment of the present invention.

FIG. 5 shows a side view of the memory module according to the first embodiment of the present invention.

FIG. 6 shows a partially cross-sectional view of the memory module according to the first embodiment of the present invention.

FIG. 7 shows a top view of another memory module according to the second embodiment of the present invention.

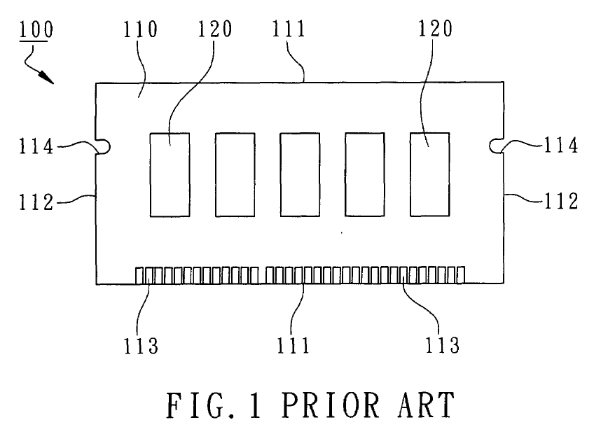

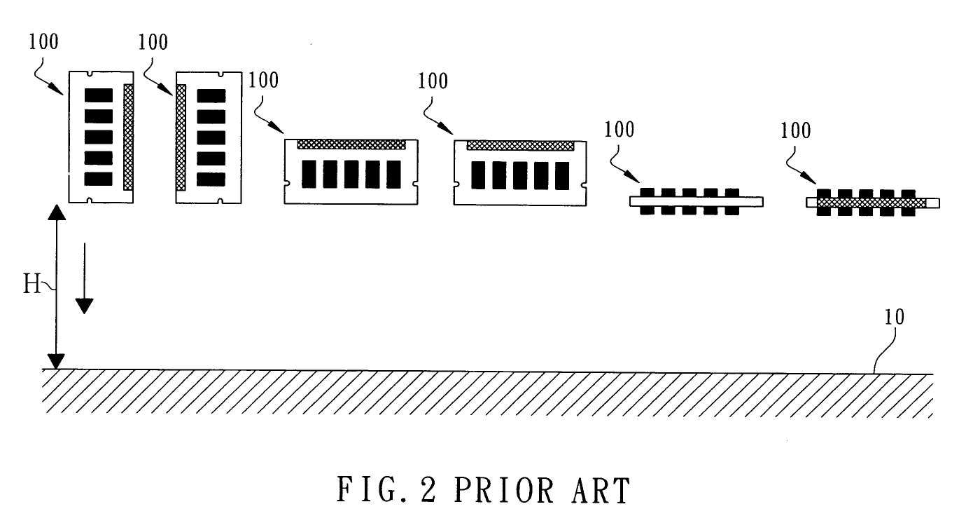

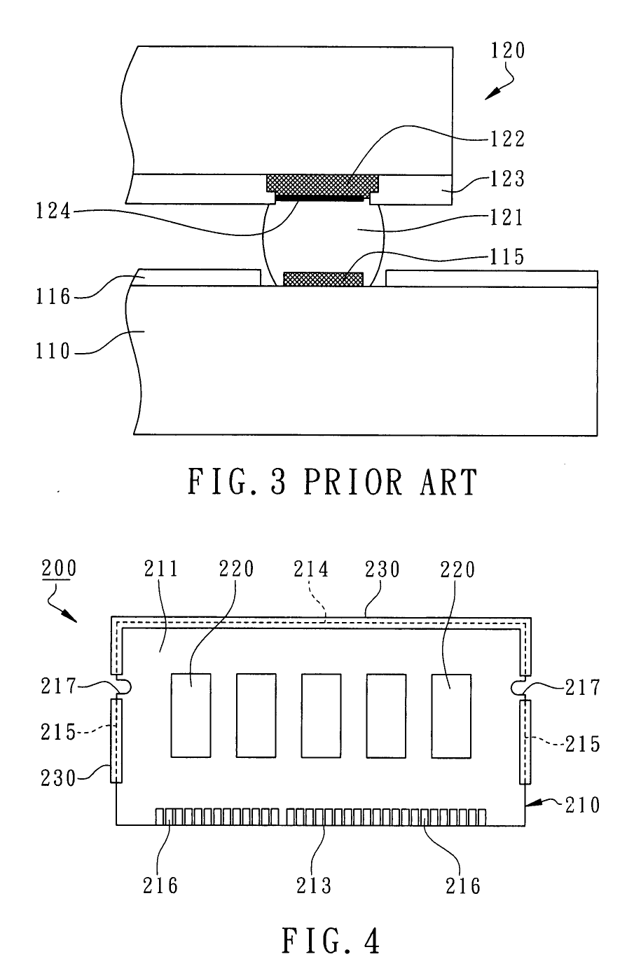

### DETAIL DESCRIPTION OF THE INVENTION

Please refer to the attached drawings, the present invention will be described by means of embodiment(s) below.

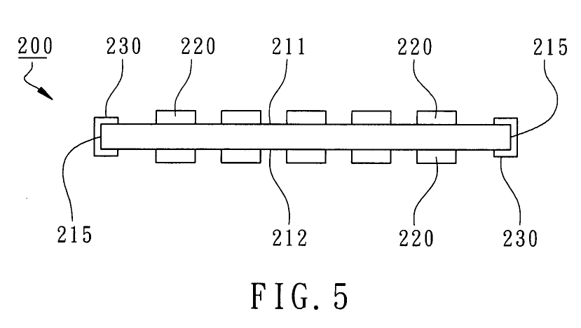

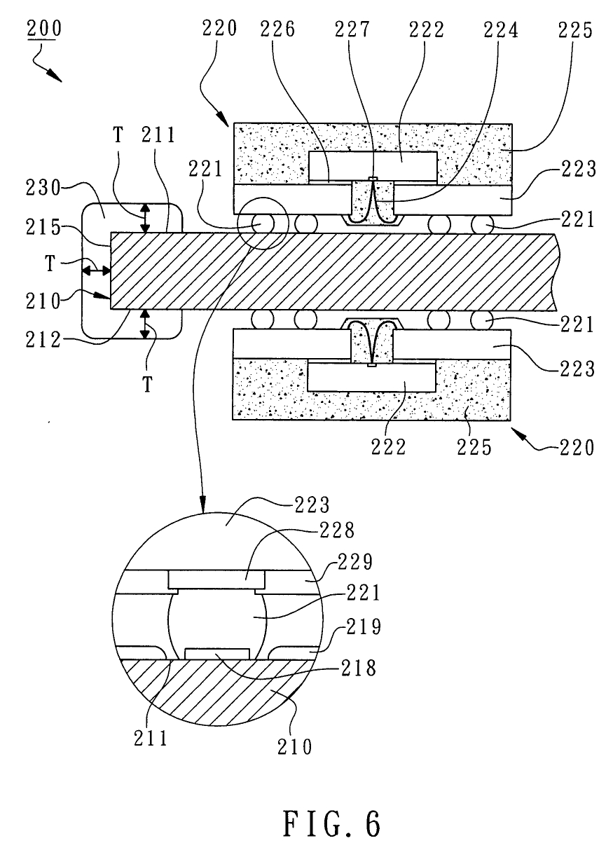

According to the first embodiment of the present invention, as shown in FIG. 4, FIG. 5, and FIG. 6, a memory module 200 primarily comprises a multi-layer printed circuit board (PCB) 210, a plurality of memory packages 220, and a stress-buffering layer 230. The memory module 200 further comprises a plurality of passive components, not shown in the figure, disposed on the PCB 210.

As shown in FIG. 4 and FIG. 5, the PCB 210 has a rectangular first surface 211, a rectangular second surface 212, a first long side 213, a second long side 214, and two short sides 215 where a plurality of gold fingers 216 are disposed on both surfaces of the first long side 213, i.e., on the same sides of the first surface 211 and the second surface 212 for plugging into the sockets of a desk top computer or a notebook computer, not shown in the figure. Moreover, at least a locking slot 217 is formed on each short side 215 where the locking slots 217 are used to fix the memory module 200 on a mother board by locking devices on both ends of the socket. In the present embodiment, the memory module 200 is a SO-DIMM (Small Outline Dual In-line Memory Module) for notebook computers.

The memory packages 220 at least are disposed on one of the surface of the PCB 210 such as only on the first surface 211, or only on the second surface 212, or on both the first surface 211 and the second surface 212. As shown in FIG. 5 and FIG. 6, in addition to the first surface 211, parts of the memory packages 220 are disposed on the second surface 212 of the PCB 210. As shown in FIG. 6, in the present embodiment, the memory packages 220 can be BGA (Ball Grid Array) packages comprising a plurality of solder balls 221. The memory packages 220 can be fine-pitch BGA packages or window BGA packages where a memory chip 222 is disposed inside the packages. The memory chip 222 can be a DRAM chip, a DDR II DRAM chip, a DDR III DRAM chip, or a Rambus DRAM chip. Each memory package 220 further comprises a substrate 223 for transmitting electrical signals, a plurality of bonding wires 224 for internal electrical interconnections between the chip 222 and the substrate 223, and an encapsulant 225 encapsulating parts or the whole of the chip 222 for electrical isolation. The chip 222 is disposed on the substrate 223 by a die-attaching layer 226 where the bonding pads 227 of the chip 222 are aligned within a slot of the substrate 223. The bonding pads 227 of the chip 222 are electrically connected to the substrate 223 by the bonding wires 224 passing through the slot on the substrate 223 where the bonding wires 224 and the chip 222 are then encapsulated by the encapsulant 225. Solder balls 221 are disposed on the ball pads 228 on the other surface of the substrate 223 where the ball pads 228 are exposed from the solder mask 229 on the same surface of the substrate 223. Normally the ball pads 228 can be SMD (Solder Mask Defined pad) or NSMD (Non-Solder Mask Defined pad). The SMD pad is defined as the peripheries of the ball pads 228 are covered by the solder mask 229, i.e., the opening diameters of the solder mask 229 are smaller than the ones of the ball pads 228 by using round pads as an example. Accordingly, the NSMD pad is defined as the peripheries of the ball pads 228 are not covered by the solder mask 229, i.e., the opening diameters of the solder mask 229 are larger than the ones of the ball pads 228.

As shown in FIG. 6, a plurality of ball pads 218 are disposed at least on the first surface 211 of the PCB 210 for disposing the solder balls 221 of the memory packages 220. Preferably, the ball pads 218 are NSMD pads, i.e., the sidewalls of the ball pads 218 are not covered nor defined by the solder mask 219 of the PCB 210 to enhance the adhesion strength of the corresponding solder balls 221 and to prevent the broken interfaces between the ball pads 218 and the solder balls 221. However, the ball pads 218 can also be SMD pads.

Referring to FIGS. 4, 5, and 6 again, the stress-buffering layer 230 is disposed on two short sides 215 of the PCB 210 and extended to the first surface 211 and the second surface 212 so that the stress-buffering layer 230 has a U-shaped cross-section. Therein, the material of the stress-buffering layer 230 can be chosen from a group of rubber, silicon rubber, and polyimide which are relatively softer than the materials of the PCB 210. Usually, the thickness of the stress-buffering layer 230 ranges from 0.5 mm to 1.5 mm. As shown in FIG. 6, the thicknesses T of the stress-buffering layer 230 on the first surface 211, the second surface 212, and on the short sides may be controlled to be the same. Moreover, the stress-buffering layer 230 can be formed by dipping or printing. Before covered by the stress-buffering layer 230, the two short sides 215 are singulated first with the core and some of metal traces of the PCB 210 exposed. Preferably, the stress-buffering layer 230 is moisture-proof to prevent moisture diffusing into the PCB 210 by the sidewalls to enhance anti-moisture and reliability of the products. In the present embodiment, the stress-buffering layer 230 can be continuously disposed and can further be disposed on the second long side of the PCB 210. However, the stress-buffering layer 230 is not disposed on the first long side 213 where gold fingers 216 are disposed without hindering the plugging of the memory module 200 for electrical connections. Furthermore, the stress-buffering layer 230 is not disposed in the locking slot 217 without hindering the locking of the memory module 200 for mechanical fixing.

When the memory module 200 is dropped by accident or during a drop test, the stress-buffering layer 230 will hit the ground first and absorb and disperse the impact stress to avoid directly passing the impact stress to the memory packages 220. Therefore, the interfaces between the solder balls 221 and the ball pads 228 will not easily be broken. The stress-buffering layer 230 has an obvious function of anti-impact caused by dropping.

In the second embodiment, another memory module capable of lessening shock stresses is revealed for desktop computers such as DDR II-400, DDR II-533, DDR II-667, DDR II-800, or DDR III memory modules.

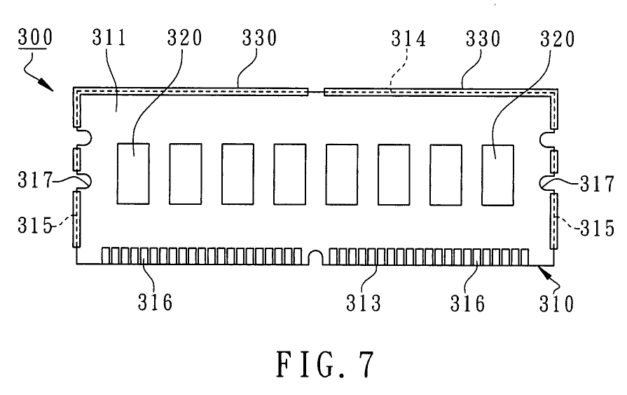

As shown in FIG. 7, a memory module 300 primarily comprises a PCB 310, a plurality of memory packages 320, and a stress-buffering layer 330. The PCB 310 has a rectangular first surface 311, a rectangular second surface opposing to the first surface 311, a first long side 313, a second long side 314, and two short sides 315 where a plurality of gold fingers 316 are disposed on both surfaces of the first long side 313. The memory packages 320 are at least disposed on one of the surface of the PCB 310, i.e., on the first surface 311 or/and on the second surface.

The stress-buffering layer 330 is at least disposed on both short sides 315 of the PCB 310 and extended to the first surface 311 and the second surface, not shown in the figure. The Young's modulus of the stress-buffering layer 330 is relatively small compared to the one of PCB 310. In the present embodiment, the stress-buffering layer 330 can be discontinuous to avoid peeling of the stress-buffering layer 330. Therefore, the stress-buffering layer 330 is disposed in designated locations to reduce the impact stresses to prevent broken interfaces between the PCB 310 and the memory packages 320 so that the stress-buffering layer 330 has an obvious function of anti-impact caused by dropping.

The above description of embodiments of this invention is intended to be illustrative and not limiting. Other embodiments of this invention will be obvious to those skilled in the art in view of the above disclosure.

What is claimed is:

1. A memory module comprising:
a multi-layer printed circuit board (PCB) having a rectangular first surface, a rectangular second surface, a first long side, a second long side, and two short sides, the PCB including a plurality of gold fingers disposed on both surfaces of the first long side and a locking slot disposed on each short side;
a plurality of memory packages disposed at least on the first surface of the PCB; and
a stress-buffering layer disposed on both short sides of the PCB and extended to the first surface and the second surface.

2. The memory module of claim 1, wherein the memory packages are BGA packages with a plurality of solder balls.

3. The memory module of claim 2, wherein the PCB further includes a plurality of ball pads disposed on the first surface for disposing the solder balls.

4. The memory module of claim 3, wherein the ball pads are Non-Solder Mask Defined (NSMD) pads.

5. The memory module of claim 1, wherein the stress-buffering layer is moisture-proof.

6. The memory module of claim 1, wherein the stress-buffering layer is further disposed on the second long side.

7. The memory module of claim 1, wherein the stress-buffering layer is discontinuously disposed.

8. The memory module of claim 1, wherein the stress-buffering layer is not disposed in the locking slots.

9. The memory module of claim 1, wherein the stress-buffering layer is not disposed on the first long side.

10. The memory module of claim 1, wherein some of the memory packages are disposed on the second surface of the PCB.

11. The memory module of claim 1, wherein the stress-buffering layer has a U-shaped cross-section.
